(19) United States
(12) Patent Application Publication
(10) Pub. No.: US 2007/0209759 A1
(43) Pub. Date: Sep. 13, 2007

(54) Plasma etching apparatus and plasma etching method

(76) Inventors: Go Miya, Tokyo (JP); Naoshi Itabashi, Tokyo (JP); Seiichiro Kanno, Tokyo (JP); Akitaka Makino, Hikari-shi (JP); Hiroshi Akiyama, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/501,814

(22) Filed: Aug. 10, 2006

(30) Foreign Application Priority Data
Mar. 7, 2006 (JP) 2006-060934

(51) Int. Cl. H01L 21/306; C23F 1/00

(52) U.S. Cl. 156/345.33; 438/706; 438/710; 156/345.35; 156/345.42

(57) ABSTRACT

In performing plasma etching with the aim to form a gate electrode on a large-diameter substrate, it is difficult according to prior art methods to ensure the in-plane uniformity of CD shift of the gate electrode. The present invention solves the problem by supplying processing gases having different flow rates and compositions respectively through openings formed at positions opposing to the substrate and at the upper corner or side wall of the processing chamber.

The present application is based on and claims priority of Japanese patent application No. 2006-60934 filed on Mar. 7, 2006, the entire contents of which are hereby incorporated by reference.

### BACKGROUND OF THE INVENTION

1. Field of the invention

The present invention relates to a plasma etching apparatus and a plasma etching method for processing semiconductor substrates such as semiconductor wafers.

2. Description of the related art

In the process for manufacturing semiconductor devices, plasma etching apparatuses utilizing reactive plasma are used for processing semiconductor substrates such as semiconductor wafers.

One example of plasma etching is described with reference to FIGS. 9A and 9B, illustrating an etching process for forming a polysilicon (Poly-Si) gate electrode for a metal oxide semiconductor (MOS) transistor (hereinafter referred to as gate etching). As shown in FIG. 9A, a silicon dioxide (SiO2) film 3, a polysilicon film 4 and a photoresist mask 6 are formed sequentially in the named order on the surface of a silicon (Si) substrate 2 of a substrate 1 prior to etching. The gate etching process is a process for exposing the wafer 1 to reactive plasma and removing the polysilicon film 4 in the area not covered by the photoresist mask 6, and forming a gate electrode 7 by this gate etching process, as shown in FIG. 9B.

The gate width 9 of the gate electrode 7 has a strong influence on the performance of the semiconductor device, so it is supervised strictly as critical dimension (CD). The value obtained by subtracting from the gate width 9 the width 8 of the photoresist mask prior to processing is called a CD shift, which is an important indicator representing the performance of the etching process, and the target value thereof is determined in advance for the etching process.

FIGS. 10A and 10B illustrate a prior art example of the plasma etching apparatus for performing gate etching.

FIG. 10A illustrates an upper view of the plasma etching apparatus, and FIG. 10B shows a cross-sectional side view of the plasma etching apparatus. A processing chamber roof 22 and a shower head plate 24 are disposed on top of the processing chamber wall 20. As shown in FIG. 10A, a substrate holder 28 is disposed in the processing chamber 26 defined by the processing chamber wall 20, the processing chamber roof 22 and the shower head plate 24. Processing gas 36 is supplied into a space 32 formed between the processing chamber roof 22 and the shower head plate 24 through a supply pipe 30 disposed on the upper portion of the processing chamber wall 20, and the processing gas 36 is supplied into the processing chamber 26 via a gas supply port 34 composed of a plurality of holes formed on the shower head plate 24.

An RF applying coil 150 is disposed on top of the processing chamber roof 22. As shown in FIG. 10A, an RF power supply 154 connected to an RF supply unit 152 formed on one end of the RF applying coil 150 applies RF with a frequency of 13.56 MHz to the RF applying coil 150, and by the inductive coupling action thereof, plasma 38 is generated as shown in FIG. 10B. The plasma etching process is performed by exposing the substrate 1 to plasma 38. The volatile substances generated by the reaction of the plasma etching process and the processing gas 36 are discharged through an exhaust port 40. A vacuum pump (not illustrated) is connected to the end of the exhaust port 40, by which the pressure in the processing chamber 26 is reduced to approximately 0.5 to 1 Pascal (Pa).

Gate etching is performed using the plasma etching apparatus as described above, but along with the recent increase in size of the substrate 1, it is becoming more and more difficult to ensure the aforementioned CD shift in the gate etching process and the in-plane uniformity of the shape of the gate electrode 7. At the same time, the demands related to CD shift control are becoming stricter with the recent miniaturization of the semiconductor devices.

Next, we will describe the deposition or adhesion of reaction products on the side wall of the gate electrode, which is one of the causes that affect the CD shift. Conventionally, a plurality of gases such as chloride (C12), hydrogen bromide (HBr) and oxygen (O2) are used for gate etching. During etching, the gases are in the state of plasma generating etchants, and when the polysilicon film 4 is subjected to etching, the ions and radicals of Cl (chlorine), H (hydrogen), Br (bromine) and oxygen (O) created by the chlorine, hydrogen bromide and oxygen contained in the processing gas 36 being dissolved react with silicon generated from the polysilicon film 4, generating reaction products. The volatile substances contained in the reaction products are evacuated through the exhaust port 40, but the nonvolatile substances in the reaction products become depositing components, attaching to and depositing on the polysilicon film 4 and the photoresist mask 6.

The depositing components depositing on the side wall of the gate electrode 7 function as a protecting film protecting the side wall from isotropic etching by radicals of etchants such as chlorine during the etching process. Therefore, if only a small amount of depositing components is deposited on the side wall of the gate electrode 7, the isotropic etching by the radicals on the side wall of the gate electrode 7 is promoted, and the gate width 9 after the etching process becomes small, causing the CD shift to be decreased. On the other hand, if a large amount of depositing components is deposited on the side wall of the gate electrode 7, the components constitute a mask against etching, and the gate width 9 after the etching process becomes large, causing the CD shift to be increased.

As described, the density of reaction products affect the gate width 9 greatly, but the reaction product density near the surface of the substrate 1 may become uneven within the plane of the substrate 1, and as a result, the CD shift may become uneven within the plane of the substrate 1. For example, silicon to be subjected to etching may exist at the center of the substrate land at the surrounding areas thereof, but silicon to be subjected to etching may not exist at the outer circumference portion of the substrate 1. Therefore, even if the etch rate is uniform within the plane of the substrate 1, the density of reaction products including silicon generated from the polysilicon film 4 is high at the center portion and low at the outer circumference portion. This may also be a possible cause of in-plane unevenness of the CD shift.

Moreover, if the in-plane uniformity of etchants such as chlorine and bromine radicals and ions near the surface of the substrate 1 is not good, it may be a cause of in-plane unevenness of the etch rate and the CD shift. Similarly, if fluorocarbon-based processing gas containing carbon, such as carbon tetrafluoride (CF4), is used as the processing gas, carbon-based reaction products having strong depositing property are generated, which become depositing components that deposit on the sidewall of the gate electrode 7, possibly causing the CD shift to be increased. Therefore, if the in-plane uniformity of the density of carbon-based depositing components is not good, it may cause in-plane unevenness of the CD shift. Furthermore, the reaction products generated by the etching process combined with oxygen will have greater depositing property, which become depositing components depositing on the side wall of the gate electrode 7. Therefore, if the in-plane uniformity of the oxygen density is not good, it may become another cause of in-plane unevenness of the CD shift.

According further to the plasma etching apparatus illustrated in FIGS. 10A and 10B, RF application units 152 and 152′ must be disposed on both ends of the RF application coil 150. Therefore, the shape of the RF application coil 150 will not be axisymmetric, thus the density distribution of plasma 38 generated by the RF application coil 150 will not be axisymmetric, and the density distribution of etchants and depositing components generated in the plasma 38 will be biased.

As a result, the etching process provided to the substrate 1 will be biased, so as shown in FIG. 11, the CD shift distribution will be biased. In the illustrated example, the CD shift distribution is not axisymmetric but biased, according to which the CD shift distribution 170 of the X axis and the CD shift distribution 171 of the Y axis are not overlapped, and the left and right portions are asymmetric. In order to overcome this problem, it is inevitable to provide a plasma source capable of generating axisymmetric plasma. Further according to the prior art example, the in-plane uniformity of the depositing components and etchants near the surface of the substrate 1 is not good, and the in-plane difference of the CD shift, that is, the difference between the maximum value and the minimum value thereof, is 8 nm. In addition, the aforementioned X axis is an axis passing the notch for positioning the substrate 1 and the center of the substrate 1, and the Y axis is an axis passing the center of the substrate 1 and orthogonal to the X axis.

As described, the unevenness of the density distribution of depositing components and etchants at the surface of the substrate 1 may cause deterioration of the in-plane uniformity of CD shift. Japanese Patent Application Laid-Open Publication No. 2002-217171 (patent document 1) discloses a dry etching apparatus aimed at overcoming the above-mentioned problem by supplying gases having different compositions through a shower plate disposed at a position opposing to the wafer or substrate and through a focus ring disposed at the outer circumference side just next to the wafer.

Further, Japanese Patent Application Laid-Open Publication No. 9-115880 (patent document 2) discloses a dry etching apparatus that supplies gases having different compositions through a shower plate disposed at a position opposing to the wafer or substrate and through a ring-shaped gas supply system disposed within the processing chamber. According to this arrangement, the density distribution of etchants near the wafer can be controlled.

Though the apparatus disclosed in patent document 1 enables to control the density distribution of etchants near the wafer, it has the following drawbacks. According to the apparatus disclosed in patent document 1, the processing gases are supplied through a plurality of gas supply holes formed to the focus ring, but in the outer circumference area of the wafer, the results of the dry etching process, such as the CD shift, may differ between the areas close to the gas supply holes and areas far from the gas supply holes. Though the impact of this problem can be reduced by increasing the number of gas supply holes, it is difficult to provide a fundamental solution to this problem since the distance between the wafer and the gas supply holes is extremely short.

Furthermore, according to the apparatus disclosed in patent document 2, the ring-shaped gas supply system is disposed in the processing chamber at a region where the plasma density is high. Therefore, the amount of deposits adhered during the etching process is greater than that adhered on the processing chamber wall, and the deposits turn into particles falling on the wafer surface, possibly causing deterioration of the production yield of the semiconductor device. In order to prevent components from being subjected to adhesion of deposits, it is desirable that the components have as little unevenness as possible.

In addition, a so-called cleaning process is performed periodically in the dry etching apparatus during which plasma is generated using gases such as sulfur hexafluoride (SF6) effective for removing deposits deposited on the side wall during the etching process. If the ring-shaped gas supply system is disposed at a region where the plasma density is high, as according to the prior art example, the cleaning process must possibly be performed more frequently to remove the deposits deposited thereto. However, this will deteriorate the production throughput of the semiconductor device, that is, the number of substrates being processed per unit time, and thus is not desirable.

Further according to the prior art example, the ring-shaped gas supply system is disposed in the processing chamber, so the plasma density distribution may be changed greatly from that of existing dry etching apparatuses. Therefore, if the existing etching apparatus is replaced with the apparatus of the prior art example, the processing conditions of the plasma etching, such as the processing pressure and the applied RF power, must be changed greatly, which may be an interference to application of the etching apparatus for mass production.

### SUMMARY OF THE INVENTION

The above-mentioned problem can be solved by providing a plasma etching apparatus comprising a means for supplying into a substantially cylindrical processing chamber through different gas supply ports a plurality of processing gases having different compositions (different flow ratios for different processing gases) and flow rates using a plurality of gas supply means and a flow rate control means for controlling the gas flow rate, wherein a first gas supply port is disposed at a position opposing to the substrate and a second gas supply port is disposed so as to form uniform openings along the circumferential direction on either an upper corner portion of the processing chamber or a side wall of the processing chamber, by which a processing gas flow having superior axisymmetric property is created in the processing chamber.

The present invention enables to provide a plasma etching apparatus and a plasma etching method capable of generating an axisymmetric plasma in the processing chamber and controlling the density distribution of radicals near the surface of the substrate, so that a process having superior uniformity can be performed throughout the plane of the substrate with only a small amount of particles adhered to the substrate surface.

### BRIEF DESCRIPTION OF THE DRAWINGS

FIG. 1 is a cross-sectional view of the plasma etching apparatus according to embodiment 1 of the present invention;

FIG. 2 is a horizontal cross-sectional view of the plasma etching apparatus according to embodiment 1 of the present invention, taken at the C-C cross-section of FIG. 1;

FIG. 3 is a cross-sectional side view of the plasma etching apparatus according to embodiment 1 of the present invention, showing an enlarged view of the area around the circumference-side gas supply port;

FIGS. 4A and 4B are horizontal cross-sectional views showing the plasma etching apparatus of embodiment 1 of the present invention, wherein 4A is a horizontal cross-sectional view passing point A of FIG. 3, and 4B is a horizontal cross-sectional view passing point B of FIG. 3;

FIG. 5 is a graph showing the CD shift distribution of the surface of the substrate processed by the plasma etching apparatus according to embodiment 1 of the present invention;

FIG. 6 is a cross-sectional view showing the plasma etching apparatus according to embodiment 2 of the present invention;

FIG. 7 is a cross-sectional side view of the plasma etching apparatus according to embodiment 2 of the present invention, showing an enlarged view of the area around the circumference-side gas supply port;

FIGS. 8A and 8B are horizontal cross-sectional views showing the plasma etching apparatus of embodiment 2 of the present invention, wherein 8A is a horizontal cross-sectional view passing point D of FIG. 7, and 8B is a horizontal cross-sectional view passing point E of FIG. 7;

FIGS. 9A and 9B are cross-sectional side views of the substrate, showing states prior to gate etching and after gate etching;

FIGS. 10A and 10B are upper and cross-sectional side views of the plasma etching apparatus according to the prior art example; and

FIG. 11 is a graph showing the CD shift distribution of the surface of the substrate processed by the plasma etching apparatus according to the prior art example.

### DETAILED DESCRIPTION OF THE PREFERRED EMBODIMENTS

Now, the preferred embodiments of the present invention will be described with reference to the drawings.

### Embodiment 1

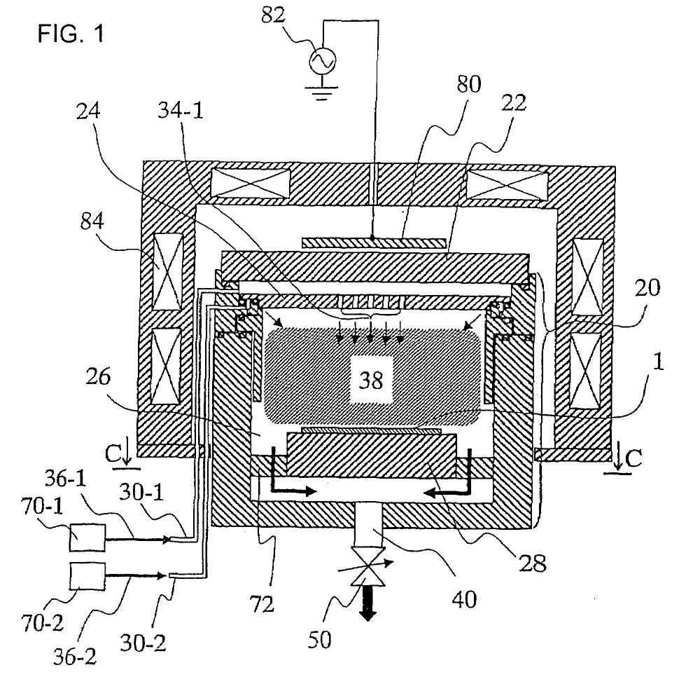

Embodiment 1 of the present invention will be described in detail with reference to FIGS. 1 through 5.

FIG. 1 is a cross-sectional view showing the structure of a UHF-ECR (ultra high frequency—electron cyclotron resonance) plasma etching apparatus to which embodiment 1 of the present invention is applied.

A processing chamber roof 22 formed of an insulating body, which according to embodiment 1 is quartz glass, is disposed on top of a substantially cylindrical processing chamber wall 20 formed of metal such as aluminum alloy or stainless steel, and a substrate stage 28 having placed thereon a substrate 1 to be processed is disposed in a processing chamber 26 defined by the above arrangement. The substrate stage 28 is fixed to the processing chamber wall 20 via plural arms 72 disposed in the circumferential direction. The processing chamber wall 20 is formed of a plurality of components, the details of which are described later.

Two systems of processing gases composed of a center-side gas system 70-1 and a circumference-side gas system 70-2 are supplied to the processing chamber 26. Each gas system is composed for example of a gas feeding means such as gas cylinders (not shown), a flow rate control means (not shown) for adjusting the flow rate of the respective gases, and a valve (not shown) for feeding and stopping the respective gases, enabling the desired gas to be supplied with a desirable flow rate or stopped.

The first processing gas 36-1 introduced to a first gas supply pipe 30-1 in the center-side gas system 70-1 is supplied to the space formed between the processing chamber roof 22 and a shower head plate 24 formed of an insulating body, which according to embodiment 1 is quartz glass. A center-side gas supply port 34-1 composed of multiple holes is formed near the center area of the shower head plate 24 disposed at a position opposing to the substrate 1, through which the first processing gas 36-1 is supplied into the processing chamber 26. Similarly, a second processing gas 36-2 introduced to a second gas supply pipe 30-2 is supplied through upper corners of the processing chamber 26, the details of which will be described later.

A substrate stage 28 is disposed inside the processing chamber 26, and a substrate 1 is placed thereon. An electrostatic chucking electrode (not shown) is embedded in the substrate stage 28, which creates an electrostatic force between the substrate 1 when DC voltage is applied thereto, and chucks the substrate 1 onto the substrate stage 28. Moreover, the substrate 1 is heated via radiation from the plasma 38 or ions generated in the plasma 38, but the heat is removed by a refrigerant (not shown) circulated in the interior of the substrate stage 28. Furthermore, an RF-applying electrode (not shown) for applying RF voltage is embedded in the substrate stage, which generates a bias potential when RF is applied thereto in order to attract the ions generated in the plasma 38 toward the substrate 1 and perform anisotropic etching.

Volatile substances generated by the first processing gas 36-1, the second processing gas 36-2 and the reaction occurring during the plasma etching process travel between the multiple arms 72 disposed in the circumferential direction and discharged through an exhaust port 40. A vacuum pump (not shown) is connected to the end of the exhaust port 40, by which the pressure within the processing chamber 26 is reduced to approximately 1 Pa (Pascal). Further, a pressure control valve 50 is disposed between the exhaust port 40 and the vacuum pump, and the pressure within the processing chamber 26 is controlled by adjusting the opening of the pressure control valve 50.

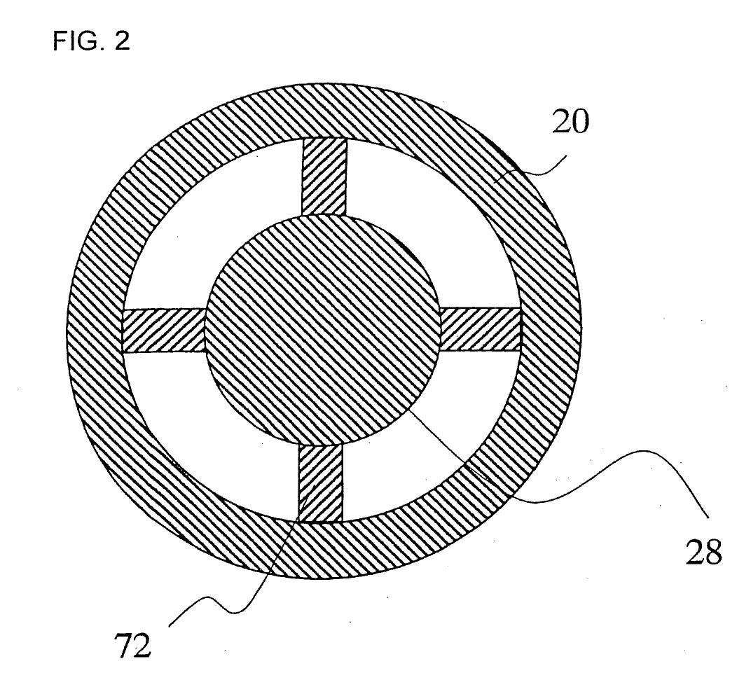

During the etching process of the substrate 1, needless to say, the etch rate distribution and CD shift distribution should preferably be uniform within the plane of the substrate 1, but actually, they tend to have certain distributions. In that case, the etch rate distribution and the CD shift distribution should preferably be distributed axisymmetricly around the center of the round substrate 1, so in order to approximate the flow of processing gases 36 to an axisymmetric flow, the arms 72 are disposed at even angular intervals in the circumferential direction, and the exhaust port 40 is disposed around the center axis of the processing chamber 26. A cross-sectional view taken at line C-C of FIG. 1 is shown in FIG. 2. The substrate stage 28 is fixed via four arms 72 disposed at even angular intervals of 90 degrees to the processing chamber wall 20. Thus, it is possible to realize a processing gas flow having good axisymmetric property.

A round antenna 80 is disposed on top of the processing chamber roof 22, and the UHF generated by a UHF power supply 82 connected to the antenna 80 is supplied from above to the antenna 80 and introduced via the processing chamber roof 22 and the shower head plate 24 formed of an insulating body, which according to embodiment 1 is quartz glass, into the processing chamber 26. Moreover, multiple ring-shaped magnetic field generating coils 84 are disposed around the processing chamber wall 20, so as to form a magnetic field, and plasma 38 is generated by the ECR action of the electromagnetic waves, which in this case are the UHF waves, and the magnetic field. At this time, by having the center axes of the round antenna 80, the ring-shaped magnetic field generating coils 84 and the substantially cylindrical processing chamber wall 20 correspond, it becomes possible to generate plasma 38 having superior axisymmetric property.

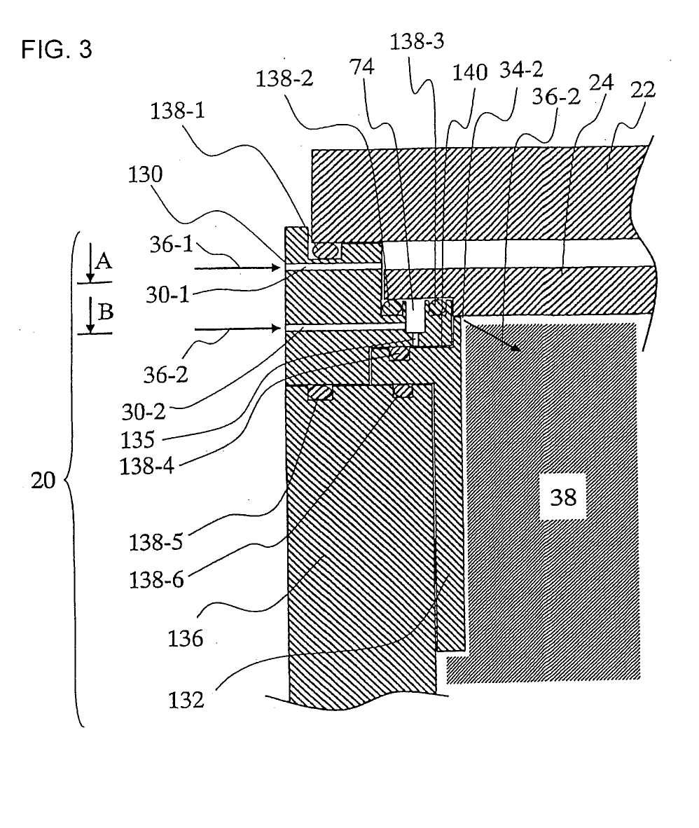

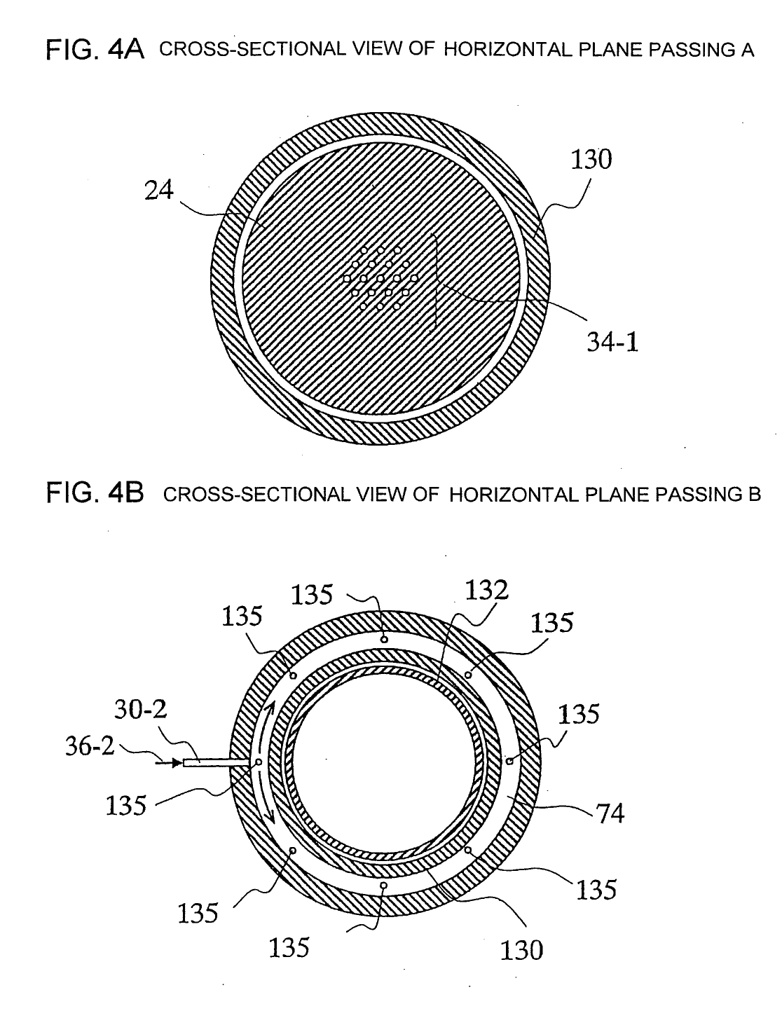

As described above, embodiment 1 realizes a structure capable of evacuating the processing gas with superior axisymmetric property and generating plasma 38 having superior axisymmetric property. Thus, the present embodiment provides a favorable structure for performing a plasma etching process having superior in-plane uniformity of etch rate and CD shift distribution. Furthermore, by having the first processing gas 36-1 and the second processing gas 36-2 supplied with superior axisymmetric property into the above-mentioned structure, the plasma etching process will realize superior in-plane uniformity of etch rate and CD shift distribution. In the following description, the structure capable of supplying the first processing gas 36-1 and the second processing gas 36-2 with superior axisymmetric property will be described in detail with reference to FIG. 3 showing an enlarged side cross-sectional view of the processing chamber wall 20 and FIGS. 4A and 4B showing a horizontal cross-section thereof.

The processing chamber wall 20 is composed of a ring 130 on which the processing chamber roof 22 and the shower head plate 24 are disposed, an earth ring 132 exposed to the area where the density of plasma 38 is high, and a processing chamber base 136 placed below the earth ring 132 and the ring 130. Grooves are formed in the circumferential direction at contact portions between these components, and by placing O-rings 138-1 through 138-6 thereto, the processing chamber can be maintained airtight and at reduced pressure.

FIG. 4A shows a cross-sectional view taken at a horizontal plane passing portion A of FIG. 3. The center axes of the substantially cylindrical ring 130 and the shower head plate 24 are conformed, and the center-side gas supply port 34-1 is disposed at the center portion of the shower head plate 24. Thereby, the flow of the first processing gas 36-1 supplied through the center-side gas supply port 34-1 in the processing chamber 26 will be axisymmetric, and thus the distribution of etching results (such as the etch rate and the CD shift) of the substrate 1 becomes axisymmetric.

The second processing gas 36-2 introduced to a second gas supply pipe 30-2 is supplied to a gas supply groove 74 having a rectangular cross-sectional shape. The gas supply groove 74 is defined in the area surrounded by a groove formed to the whole circumference of the ring 130 in the circumferential direction and the shower head plate 24. The gas supply groove 74 has multiple holes 135 formed to pass through in the lower direction and disposed in the circumferential direction. A gap 140 having a certain height is formed between the ring 130 and the earth rig 132, and the second processing gas 36-2 traveling through the second gas supply pipe 30-2 passes through the gap 140, and thereafter, is supplied into the processing chamber 26 through a circumference-side gas supply port 34-2 defined by the gap formed between the shower head plate 24 and the earth ring 132.

In order for the CD shift to be as uniform as possible in the etching process of the substrate 1, it is desirable to reduce the circumferential bias of supply quantity of the second processing gas 36-2 supplied to each hole 135, and in order to do so, it is necessary that the differences in pressure at the upper stream side of each of the holes 135 are small. Thus, careful consideration must be directed to determine the size of the gas supply groove 74, the size of the holes 135, the size of the gap 140 and the size of the circumference-side gas supply port 34-2. At first, in order to reduce the circumferential bias of the supply quantity of the processing gases introduced to each of the holes 135, it is necessary that the conductance for the gas to flow in the circumferential direction in the gas supply groove 74 (which is referred to as Cg) is much greater than the conductance of the hole 135 (which is referred to as Ch).

If this condition is not satisfied, when the second processing gas 36-2 supplied through the second gas supply pipe 30-2 travels through the gas supply groove 74 in the directions of the arrows in FIG. 4B illustrating the flow of the second processing gas, a large amount of gas will flow out through the holes 135 and 135′ close to the second gas supply pipe 30-2 and only a small amount of second processing gas 36-2 will be supplied through the hole 135″ which is farthest from the second gas supply pipe 30-2. As a result, a circumferential bias will occur to the etching process results (such as the etch rate and the CD shift) of the substrate 1.

In order to overcome this problem, it is necessary that the differences in pressure at the upper stream side of each of the holes 135 are small, as described earlier. The method for computing the pressure at the upper stream side of each of the holes 135 will now be described. When the flow rate of the second processing gas 36-2 is set to 10 sccm (standard cc/min) and the pressure within the processing chamber is approximately 1 Pa, the pressure within the gas supply groove 74 will be around 500 to 1000 Pa, and the Knudsen number (the ratio between the mean free path of molecules of the second processing gas 36-2 and the representative size thereof) within the gas supply groove 74 having a length in the order of mm (millimeters) will be smaller than 0.1, according to which the gas flow becomes a viscous flow. In this case, when the height of the gas supply groove 74 is h (the unit being m (meters)), the width is w (the unit being m (meters)), the coefficient determined by h and w is Y, the distance between adjacent circumference-side gas supply ports 34-2 is L (the unit being m (meters)), the average pressure within the gas supply groove 74 between adjacent circumference-side gas supply ports 34-2 is P (the unit being Pa (Pascal)) and the viscosity of the second processing gas 36-2 is p (the unit being Pa×s (the product of Pascal and second)), then Cg (the unit being m³/s (cubic meter/second)) is given by expression 1.

$$C g = 1.139 \times {10}^{- 4} \times Y \times \frac{{h}^{2} {w}^{2}}{L} \times P \times μ [ {m}^{3} \text{/} s ] \qquad [ Expression 1 ]$$

On the other hand, the gas flow within the hole 135 will either be viscous flow or intermediate flow between viscous flow and molecular flow. In the case of an intermediate flow between viscous flow and molecular flow, when the length and the inner diameter of the hole 135 are LL and D (the unit being m (meter)), respectively; the temperature, the molecular weight and the viscosity of the second processing gas 36-2 are T (the unit being K (Kelvin)), M (the unit being kg/mol (kilogram/mole)) and p (the unit being Pa×s (the product of Pascal and second)); the pressure of the second processing gas 36-2 within the circumference-side gas supply port 34-2 is PP; the circular constant is n; and the general gas constant is R (the unit being J/(mol×K) (joule/(mole×Kelvin))); then Ch (the unit being m³/S (cubic meter/second)) is given by expression 2.

$$C h = \frac{π}{128} \frac{{D}^{4}}{μ \cdot L L} P P + \frac{1}{6} \sqrt{\frac{2 π R T}{M}} \frac{{D}^{3}}{L L} \frac{1 + 13.33 \frac{D \cdot P P}{μ} \sqrt{\frac{M}{R T}}}{1 + 16.53 \frac{D \cdot P P}{μ} \sqrt{\frac{M}{R T}}} [ {m}^{3} \text{/} s ] \qquad [ Expression 2 ]$$

By utilizing the above-described conductance Cg and Ch, the quantity of the supplied second processing gas 36-2 and the pressure within the processing chamber 26, the pressure at the upper stream of each hole 135 can be computed. However, since pressure is included as a variable in expressions 1 and 2, the pressure is obtained by performing repeated calculation and converging the value. As a result of such calculations, it is possible to determine whether the values for each of the sizes mentioned earlier are appropriate or not.

In embodiment 1, by setting the height h of the gas supply groove 74 to 0.005 m, the width w to 0.004 m, the distance L between adjacent holes 135 to 0.05 m, the viscosity μ of the second processing gas 36-2 to 1.5×10−5 Pa×s, the length LL of the hole 135 to 0.01 m, the inner diameter D to 0.001 m, the temperature T to 300 K and the molecular weight M of the second processing gas 36-2 to 74 g/mol, the differences in pressure at the upper stream of the holes 135 can be suppressed to within 1% of the absolute value of pressure, and the circumferential bias can be minimized.

Moreover, the second processing gas 36-2 passing through the outlets of the holes 135 travels through the gap 140 formed between the ring 130 and the earth ring 132, and is supplied through the circumference-side gas supply port 34-2 into the processing chamber 26. At this time, as the space of the gap 140 or the height of the circumference-side gas supply port 34-2 increases, the circumferential bias of the supply quantity of the second processing gas 36-2 supplied through the circumference-side gas supply port 34-2 reduces. However, if the distance of the gap 140 or the height of the circumference-side gas supply port 34-2 is too large, charged particles such as ions generated in plasma 38 may enter the circumference-side gas supply port 34-2, causing abnormal electrical discharge. Further, the reaction products generated during the plasma etching process may enter the circumference-side gas supply port 34-2, travel upstream and deposit thereon, becoming the cause of particles. Therefore, the gap 140 and the height of the circumference-side gas supply port 34-2 should be set to appropriate sizes. In embodiment 1, the sizes are set to 0.001 m. Thereby, the circumferential bias of the supply quantity of the second processing gas 36-2 supplied through the circumference-side gas supply port 34-2 is suppressed to 0.1% or lower of the absolute value of the supply quantity, and at the same time, the abnormal electrical discharge or the deposition of reaction products can be prevented. As described, embodiment 1 enables the second processing gas 36-2 to be introduced with superior axisymmetric property, by providing holes 135 having an extremely small conductance on the lower stream side of the gas supply groove 74 having a large conductance, and further providing on the lower stream side thereof a gap 140 having an extremely large conductance than the conductance of the holes 135.

In addition, the area of metallic components constituting the processing chamber wall 20 being exposed to corrosive gas is subjected to corrosion by the corrosive gas. Furthermore, the area of components constituting the processing chamber wall 20 coming into direct contact with plasma 38 is chemically attacked by corrosive ions and radicals such as chlorine and bromine generated in the plasma 38. At this time, the temperature of the area that comes into direct contact with plasma 38 is raised since it is directly heated by plasma 38, and even the temperature of the area not in direct contact with plasma is also raised due to heat conduction, according to which the corrosiveness of the corrosive gas and plasma is enhanced. Thus, the necessity of measures to cope with corrosion of the components constituting the processing chamber wall 20 is increased, and as a result, detailed consideration is required regarding the material and the surface treatments of the components. According to embodiment 1, corrosion is prevented by forming the ring 130 and the processing chamber base 136 with stainless steel having high corrosion resistance, and as a result, it becomes possible to prevent the heavy-metal contamination of the substrate 1.

On the other hand, since the earth ring 132 comes into contact with the region where the density of plasma 38 is high, it must have higher resistance to corrosion than the ring 130 or the processing chamber base 136, and it must be made of a material that does not cause heavy-metal contamination of the substrate 1 when corroded. Therefore, according to embodiment 1, the earth ring 132 is formed of industrial aluminum alloy, with the surface being subjected to alumite processing (anodizing process). Thus, the present embodiment realizes a plasma processing apparatus having superior resistance to plasma and that does not discharge heavy metal components like stainless steel.

Now, the method for performing plasma etching using the arrangement described above will be described in detail taking gate etching as an example. It is now assumed that when a mixed gas containing hydrogen bromide, chlorine and oxygen is used for the etching process, and 50 sccm of hydrogen bromide, 50 sccm of chlorine and 5 sccm of oxygen are respectively supplied as the first processing gas 36-1 and the second processing gas 36-2, the CD shift at the center and at the outer circumference of the substrate 1 are 10 nm and 2 nm, respectively. In this case, by either decreasing the CD shift at the center portion or increasing the CD shift at the outer circumference portion, the in-plane CD shift distribution of the substrate 1 can be made more uniform.

The CD shift at the center portion can be decreased by increasing the amount of chlorine contained in the first processing gas 36-1 supplied through the center-side gas supply port 34-1 (for example to 60 sccm), which causes the amount of chlorine radicals existing near the center portion of the substrate 1 to increase, by which the isotropic etching performed to the side wall of the gate electrode 7 is promoted and the CD shift at the center portion of the substrate is decreased. In addition, the CD shift at the center portion can also be decreased by reducing the amount of oxygen contained in the first processing gas 36-1 supplied through the center-side gas supply port 34-1 (for example to 3 sccm), which causes the amount of oxygen radicals existing near the center portion of the substrate 1 to be reduced, and the deposition of protection film deposited on the side wall of the gate electrode 7 is thus reduced.

On the other hand, the CD shift at the circumference portion can be increased by increasing the amount of oxygen contained in the second processing gas 36-2 supplied through the circumference-side gas supply port 34-2 (for example to 7 sccm), so that the amount of oxygen radicals existing near the outer circumference portion of the substrate 1 is increased, by which the deposition of protection film depositing on the side wall of the gate electrode 7 is increased and thus the CD shift at the outer circumference portion is increased. In addition, the CD shift at the outer circumference portion can also be increased by reducing the amount of chlorine contained in the second processing gas 36-2 supplied through the circumference-side gas supply port 34-2 (for example to 40 sccm), which causes the amount of chlorine radicals existing near the outer circumference portion of the substrate 1 to be reduced, by which the isotropic etching performed to the side wall of the gate electrode 7 is weakened.

Furthermore, it is assumed that when 50 sccm of hydrogen bromide, 50 sccm of chlorine and 5 sccm of oxygen are respectively supplied as the first processing gas 36-1 and the second processing gas 36-2, the CD shift at the center and at the outer circumference of the substrate 1 are 2 nm and 10 nm, respectively. In this case, by either increasing the CD shift at the center portion or decreasing the CD shift at the outer circumference portion, the in-plane CD shift distribution of the substrate 1 can be made more uniform.

The CD shift at the center portion can be increased by reducing the amount of chlorine contained in the first processing gas 36-1 supplied through the center-side gas supply port 34-1 (for example to 40 sccm), which causes the amount of chlorine radicals existing near the center portion of the substrate 1 to reduce, by which the isotropic etching performed to the side wall of the gate electrode 7 is weakened and the CD shift at the center portion of the substrate is increased. Moreover, the CD shift at the center portion can also be increased by increasing the amount of oxygen contained in the first processing gas 36-1 supplied through the center-side gas supply port 34-1 (for example to 7 sccm), which causes the amount of oxygen radicals existing near the center portion of the substrate 1 to be increased, by which the deposition of protection film deposited on the side wall of the gate electrode 7 is increased.

On the other hand, the CD shift at the circumference portion can be decreased by reducing the amount of oxygen contained in the second processing gas 36-2 supplied through the circumference-side gas supply port 34-2 (for example to 3 sccm), which causes the amount of oxygen radicals existing near the outer circumference portion of the substrate 1 to reduce, by which the deposition of protection film depositing on the side wall of the gate electrode 7 is reduced and the CD shift at the outer circumference portion can be decreased. Moreover, the CD shift at the outer circumference portion can also be decreased by increasing the amount of chlorine contained in the second processing gas 36-2 supplied through the circumference-side gas supply port 34-2 (for example to 60 sccm), which causes the amount of chlorine radicals existing near the outer circumference portion of the substrate 1 to increase, promoting the isotropic etching performed on the side wall of the gate electrode 7.

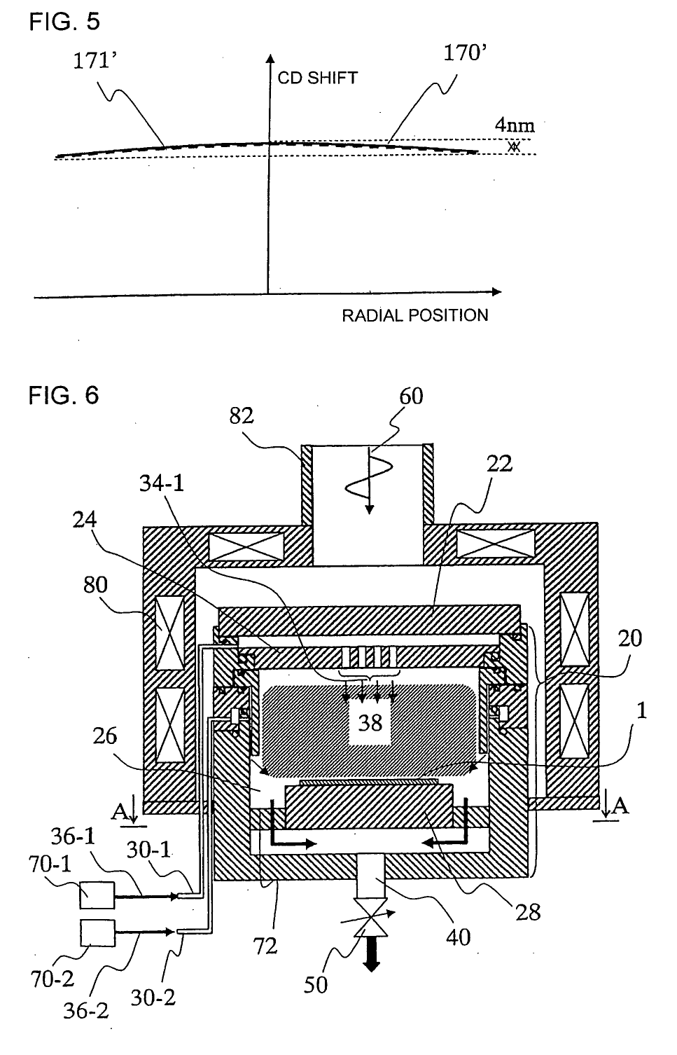

As described, the depositing components or the density distribution of etchants near the surface of the substrate 1 can be controlled by respectively supplying a first processing gas 36-1 and a second processing gas 36-2 having different compositions through the center-side gas supply port 34-1 disposed at a position opposing to the substrate 1 and the circumference-side gas supply port 34-2 formed on the upper corner portion of the processing chamber 26. As a result, it becomes possible to control the in-plane distribution of the CD shift of the substrate 1, by which the in-plane uniformity is improved. According to embodiment 1, as shown in FIG. 5, the in-plane difference of CD shift (the difference between the maximum value and the minimum value) is effectively suppressed to 4 nm. Further, the CD shift distribution 170′ along the X axis and the CD shift distribution 171′ along the Y axis at the surface of the substrate 1 are substantially overlapped, and are symmetric, meaning that an axisymmetric CD shift distribution is achieved.

Further according to embodiment 1, by having the center axis of the center-side gas supply port 34-1 for supplying the first processing gas 36-1, the center axis of the circumference-side gas supply port 34-2 for supplying the second processing gas 36-2, the center axis of the antenna 80 for applying RF, the center axis of the substantially cylindrical processing chamber wall 20, the center axis of the magnetic field forming coil 84 and the center axis of the exhaust port 40 correspond, the supply and evacuation of processing gases and the generation source of plasma 38 can be arranged coaxially, and as a result, an axisymmetric CD shift distribution is achieved.

Moreover, by arranging the circumference-side gas supply port 34-2 on the upper corner portion of the processing chamber 26, a gas supply port having little unevenness is realized, and the generation of particles is prevented. Further, the lower surface of the shower head plate 24, in other words, the area coming into contact with plasma 38, is subjected to possible deposition of particles generated during the etching process, but since the circumference-side gas supply port 34-2 is disposed on the upper corner portion of the processing chamber 26, the gas used in the cleaning process is distributed thoroughly across the whole lower surface of the shower head plate 24, by which the effect of cleaning is enhanced, preventing fall or adhesion of deposits on the surface of the substrate land reducing cleaning time. As a result, it is possible to expect improvement of the yield of the semiconductor production and the throughput thereof.

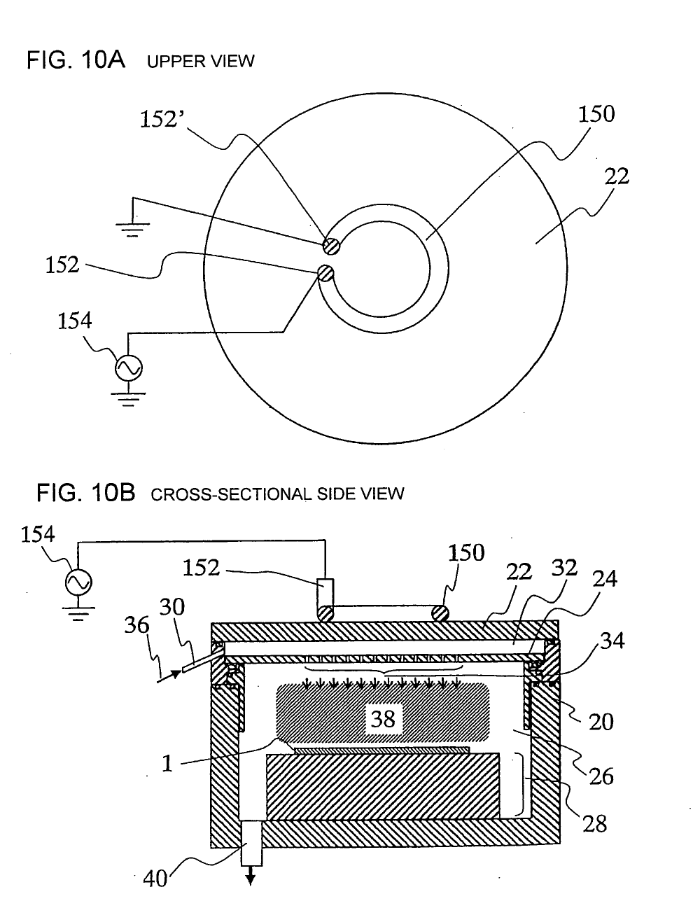

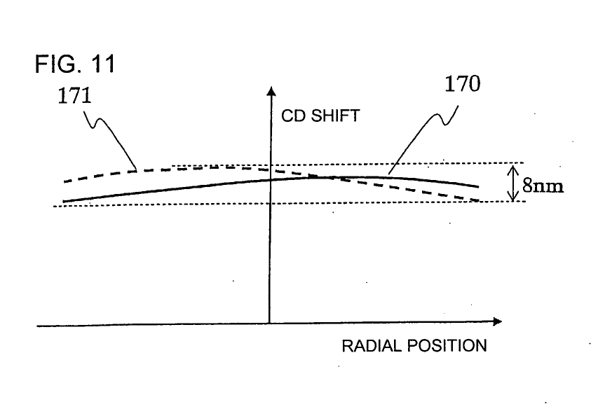

Furthermore, according to the structure shown in embodiment 1, it is possible to supply processing gases having different compositions through the center-side supply port 34-1 and the circumference-side gas supply port 34-2 so as to control the density distribution of depositing components and etchants near the substrate 1 while maintaining the shape of the region coming into contact with plasma 38 of the prior art apparatus shown in FIGS. 10A and 10B. Therefore, since it is possible to achieve a density distribution of plasma 38 equivalent to that of the prior art plasma etching apparatus, even if the prior art plasma etching apparatus is replaced with the present apparatus, the parameters other than the flow rate of processing gas 36 in the plasma etching process do not have to be changed greatly from the prior art, and the apparatus can be easily applied for mass production.

Further, a UHF-ECR plasma etching apparatus is used as an example for describing embodiment 1, but the method for generating plasma 38 is not restricted thereto. For example, other methods such as a microwave ECR method can be used.

### Embodiment 2

According to embodiment 1 of the present invention, the circumference-side gas supply port 34-2 is formed on the upper corner portion of the processing chamber 26. However, if the distance between the shower head plate 24 and the substrate 1 is long, the radicals generated from the processing gases fed from the center-side gas supply port and the circumference-side gas supply port may be mixed before reaching the substrate 1. Thus, the effect of controlling the density distribution of etchants and depositing components near the substrate 1 may undesirably be weakened.

Embodiment 2 of the present invention is devised in consideration of this problem, wherein the circumference-side gas supply port 34-2 is disposed on the side surface of the processing chamber wall 20 and at an intermediate height between the center-side gas supply port 34-1 and the substrate 1. According to this arrangement, even if the distance between the shower head plate 24 and the substrate 1 is long, the density distribution of etchants or depositing components near the substrate 1 can be controlled effectively.

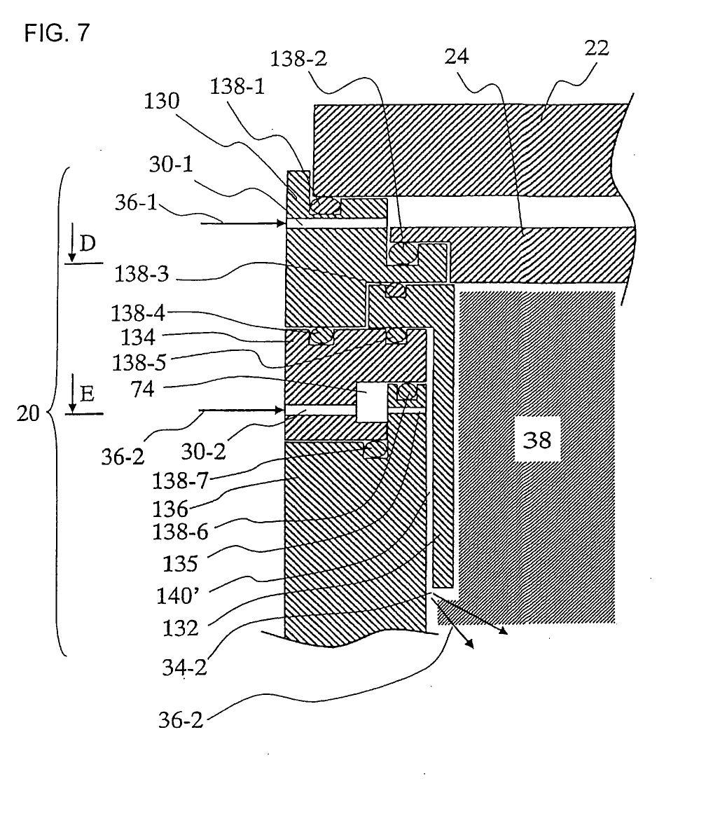

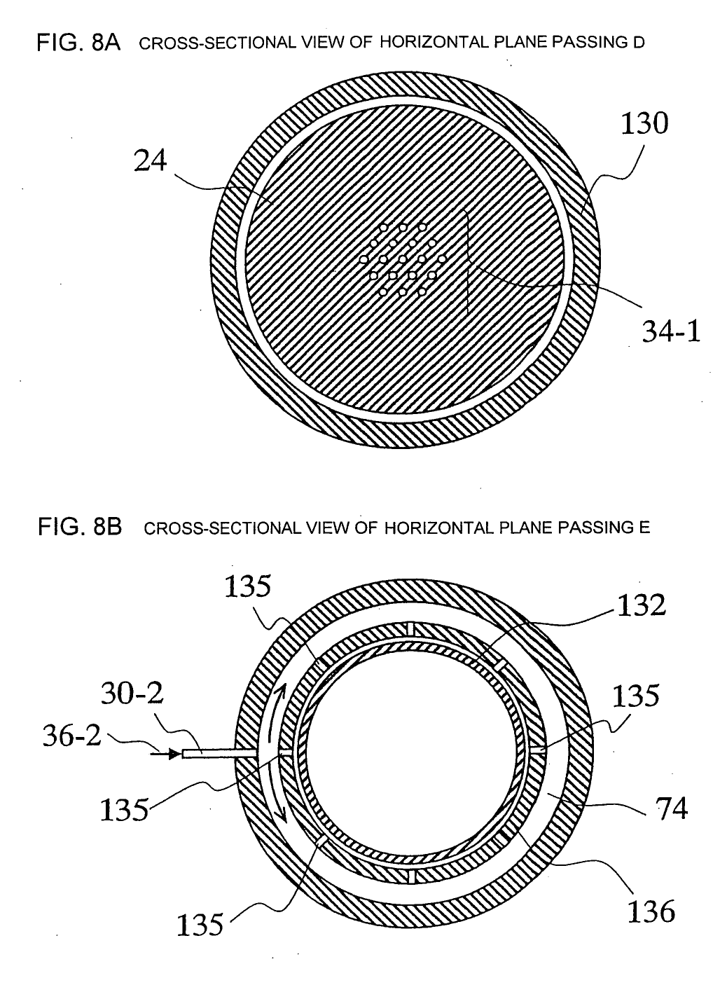

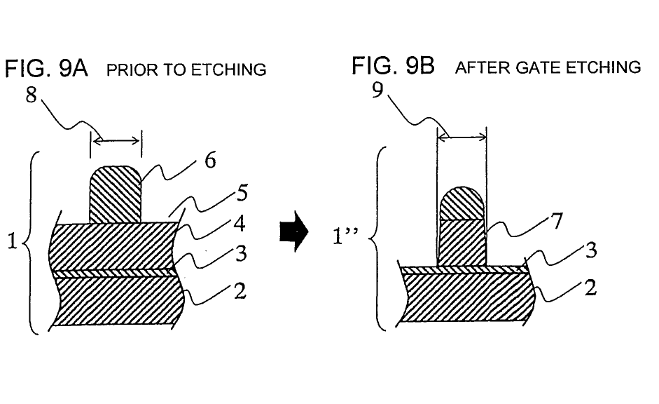

Now, embodiment 2 of the present invention will be described with reference to FIGS. 6 through 8. FIG. 6 is a view showing the structure of a microwave-ECR plasma etching apparatus according to embodiment 2 of the present invention, and FIG. 7 is a view showing in enlarged view the area around the circumference-side gas supply port 34-2. The basic structure of the plasma etching apparatus to which embodiment 2 is applied is similar to that of embodiment 1, but with the plasma generation source changed. In addition, the position of the circumference-side gas supply port 34-2 is also changed, so the arrangement constituting the processing chamber wall 20 is changed. FIGS. 8A and 8B are horizontal cross-sectional views of the plasma etching apparatus according to embodiment 2 of the present invention, where in 8A is a horizontal cross-sectional view passing line D of FIG. 7, and 8B is a horizontal cross-sectional view passing line E of FIG. 7.

At first, the plasma generation source of embodiment 2 will be described. In embodiment 2, electromagnetic waves 60 (which are microwaves according to embodiment 2) are fed via a waveguide 82 disposed above the processing chamber roof 22. The electromagnetic waves 60 are fed into the processing chamber 26 through the processing chamber roof 22 and the shower head plate 24 formed of an insulating member (which is quartz glass) Multiple circular magnetic field forming coils 84 are disposed around the processing chamber wall 20, forming a magnetic field, and plasma 38 is generated by the ECR action of the electromagnetic waves 60 (microwaves in the present embodiment) and the magnetic field. At this time, by having the center axes of the waveguide 82, the circular magnetic field forming coils 84 and the substantially cylindrical processing chamber wall 20 correspond, plasma 38 having superior axisymmetric property is generated.

Next, the mechanism for introducing the circumference-side gas supply port 34-2 will be described. The processing chamber wall 20 is composed of a ring 130 on which the processing chamber roof 22 and the shower head plate 24 are disposed, an earth ring 132 exposed to the area where the density of plasma 38 is high, a ring 134 coming into contact with the lower side of the earth ring 132 and the ring 130, and a processing chamber base 136 placed there below. Grooves are formed in the circumferential direction at contact portions between these components, and by placing O-rings 138-1 through 138-7 thereto, the processing chamber can be maintained airtight and at reduced pressure.

The second processing gas 36-2 introduced to a second gas supply pipe 30-2 is supplied to a gas supply groove 74 having a rectangular cross-sectional shape. The gas supply groove 74 is defined in the area surrounded by a groove formed along the whole circumference of the ring 134 in the circumferential direction and the processing chamber base 136. The gas supply groove 74 has multiple holes 135 disposed in the circumferential direction formed to pass through in the radial direction. A gap 140′ maintaining a certain size in the radial direction is formed between the processing chamber base 136 and the earth ring 132, and the second processing gas 36-2 traveling through the hole 135 passes through the gap 140′, and thereafter, is supplied into the processing chamber 26 through a circumference-side gas supply port 34-2 being the exit port thereof.

In order for the CD shift of the substrate 1 to be as uniform as possible in the etching process, it is preferable to reduce the circumferential bias of supply quantity of the second processing gas 36-2 supplied to each hole 135, and in order to realize the same, it is necessary that the differences in pressure at the upper stream side of each of the holes 135 are small. Thus, careful consideration must be directed in determining the size of the gas supply groove 74, the size of the hole 135 and the size of the gap 140′.

At first, in order to reduce the circumferential bias of the supply quantity of the processing gases introduced to the holes 135, it is necessary that the conductance for the gas to flow in the circumferential direction in the gas supply groove 74 (which is referred to as Cg) is set much greater than the conductance of the hole 135 (which is referred to as Ch). If this condition is not satisfied, there will be differences in pressure at the upper stream side of the respective holes 135, and as a result, a greater amount of second processing gas 36-2 will be supplied into a hole 135 having a higher upper-stream pressure than the other holes 135, and thus, a circumferential bias will occur in the etching process results (such as the CD shift) of the substrate 1.

As described in embodiment 1, Cg and Ch are respectively expressed by expressions 1 and 2. In embodiment 2, by setting the height h of the gas supply groove 74 to 0.005 m, the width w to 0.004 m, the distance L between adjacent holes 135 to 0.05 m, the viscosity p of the second processing gas 36-2 to 1.5×10−5 Pa×s, the length LL of the hole 135 to 0.01 m, the inner diameter D to 0.001 m, the temperature T to 300 K and the molecular weight M of the second processing gas 36-2 to 74 g/mol, the differences in pressure at the upper stream of the respective holes 135 can be suppressed to within 1% of the absolute value of pressure.

Moreover, the second processing gas 36-2 passing through the outlets of the holes 135 travels through the gap 140′ formed between the processing chamber base 136 and the earth ring 132, and is supplied through the circumference-side gas supply port 34-2 into the processing chamber 26. At this time, as the distance of the gap 140′ increases, the circumferential bias of the second processing gas 36-2 supplied through the gap 140′ reduces. However, if the space of the gap 140′ is too large, charged particles such as ions generated in plasma 38 may enter the circumference-side gas supply port 34-2, possibly causing abnormal electrical discharge. Further, the reaction products generated during the plasma etching process may enter the circumference-side gas supply port 34-2, travel upstream and deposit thereon, becoming the cause of particles.

Therefore, the distance of the gap 140′ in the radial direction must be set to an appropriate size. In embodiment 2, the distance of the gap 140′ is set to 0.001 m. Thereby, the circumferential bias of the supply quantity of the second processing gas 36-2 supplied through the circumference-side gas supply port 34-2 is suppressed to 0.1% or lower of the absolute value of the supply quantity, and at the same time, the abnormal electrical discharge or the deposition of reaction products can be prevented.

As described, embodiment 2 enables the second processing gas 36-2 to be supplied with superior axisymmetric property, by providing holes 135 having an extremely small conductance compared to the conductance of the gas supply groove 74 on the lower stream side of the gas supply groove 74 having a large conductance, and further providing on the lower stream side thereof a gap 140′ having an extremely large conductance compared to the conductance of the holes 135.

The processing method for performing plasma etching using the arrangements described above is similar to that described in embodiment 1. Thus, by introducing the first processing gas 36-1 and the second processing gas 36-2 having different compositions from the center-side gas supply port 34-1 and the circumference-side gas supply port 34-2, it becomes possible to control the density distribution of etchants and depositing components near the substrate 1, and as a result, the in-plane distribution of CD shift of the substrate 1 can be controlled. At this time, by disposing the circumference-side gas supply port 34-2 to the side surface of the processing chamber wall 20 and at an intermediate height between the center-side gas supply port 34-1 and the substrate 1, the in-plane distribution of the CD shift of the substrate 1 can be controlled effectively even when the distance between the shower head plate 24 and the substrate 1 is long. Furthermore, by placing the circumference-side gas supply port 34-2 between the processing chamber base 136 and the earth ring 132, the gas supply port will have little unevenness, and the generation of particles can be prevented.

Furthermore, according to embodiment 2, by having the center axis of the center-side gas supply port 34-1 for supplying the first processing gas 36-1, the center axis of the circumference-side gas supply port 34-2 for supplying the second processing gas 36-2, the center axis of the waveguide 82 for applying the electromagnetic waves, the center axis of the substantially cylindrical processing chamber wall 20, the center axis of the magnetic field forming coil 84 and the center axis of the exhaust port 40 correspond, the supply and evacuation of processing gases and the generation source of plasma 38 can be arranged coaxially, and as a result, an axisymmetric CD shift distribution is achieved.

Moreover, by arranging the circumference-side gas supply port 34-2 between the processing chamber base 136 and the earth ring 132, a gas supply port having reduced unevenness is realized, and the generation of particles is prevented. Moreover, according to the arrangement illustrated in embodiment 2, the processing gases having different compositions can be supplied through the center-side supply port 34-1 and the circumference-side gas supply port 34-2 while maintaining the shape of the region coming into contact with plasma 38 of the prior art apparatus shown in FIG. 10, thereby enabling to control the density distribution of the depositing components and etchants near the substrate 1. Therefore, since it is possible to achieve a density distribution of plasma 38 equivalent to that of the prior art plasma etching apparatus, even if the prior art plasma etching apparatus is replaced with the present apparatus, the parameters other than the flow rate of processing gas 36 in the plasma etching process do not have to be changed greatly from the prior art, and the apparatus can be easily applied for mass production.

Further, a microwave-ECR plasma etching apparatus is used as an example for describing embodiment 2, but the method for generating plasma 38 is not restricted thereto. For example, other methods such as the UHF-ECR method can be used.

### Embodiment 3

Embodiments 1 and 2 illustrate the structure of a plasma etching apparatus and a processing method using the plasma etching apparatus. According to these embodiments, processing gas containing halogen such as chlorine and hydrogen bromide is used as the second processing gas 36-2. In contract, we will now describe as embodiment 3 of the present invention a processing method that supplies only non-corrosive processing gas such as oxygen as the second processing gas 36-2, aimed at preventing corrosion of the gas supply groove 74 and the circumference-side gas supply port 34-2, and considering long-term operation of the plasma etching apparatus. The apparatus used for carrying out the plasma etching method according to embodiment 3 can have the arrangement of either embodiment 1 or embodiment 2, but in the following description, the plasma etching apparatus illustrated in embodiment 1 is used as the example.

As described earlier, by forming the components constituting the processing chamber wall 20 with stainless steel material, it is possible to prevent the corrosion caused by halogen-based gases contained in the second processing gas 36-2. However, according to some processes, the processing chamber wall 20 must be heated by a heater or the like, and in that case, it may be inevitable to use an aluminum alloy material having higher thermal conductivity than stainless steel. Even in such case, it is possible to prevent the corrosion of components in short term by subjecting the aluminum to anodizing treatment, but if the corrosive property of the halogen-based gas is increased due to heating by the heater and plasma, it may not be possible to completely prevent corrosion in a long-term use of the device. In that case, the corrosion may cause deterioration of production yield of the semiconductor device.

The processing chamber roof 22 and the shower head plate 24 coming into contact with the first processing gas 36-1 is formed of quartz glass, so they will not cause metal contamination. In addition, the first gas supply pipe 30-1, the second gas supply pipe 30-2 and the upper stream areas thereof for supplying gases to the plasma etching apparatus are not subjected to corrosion since they are not heated by plasma 38, so the areas that may be subjected to corrosion are the gas supply groove 74, the holes 135 and the surrounding areas that come into contact with the second processing gas 36-2.

This problem can be solved by supplying only non-corrosive processing gases as the second processing gas 36-2. We will now describe the present processing method in detail, taking as an example a gate etching process and using the plasma etching apparatus having the same structure as that illustrated in embodiment 1 of the present invention. It is now assumed that when a mixed gas containing 100 sccm of hydrogen bromide, 100 sccm of chlorine and 5 sccm of oxygen is used as the first processing gas 36-1, and 5 sccm of oxygen is used as the second processing gas 36-2, the CD shift at the center and at the outer circumference of the substrate 1 are 5 nm and 2 nm, respectively. In this case, by either reducing the CD shift at the center portion or increasing the CD shift at the outer circumference portion, the in-plane CD shift distribution of the substrate 1 can be made more uniform.

The CD shift at the center portion can be decreased by increasing the amount of chlorine contained in the first processing gas 36-1 supplied through the center-side gas supply port 34-1 (for example to 110 sccm), which causes the amount of chlorine radicals existing near the center portion of the substrate 1 to increase, by which the isotropic etching performed to the side wall of the gate electrode 7 is promoted and the CD shift at the center portion of the substrate is decreased. In addition, the CD shift at the center portion can also be decreased by reducing the amount of oxygen contained in the first processing gas 36-1 supplied through the center-side gas supply port 34-1 (for example to 3 sccm), which causes the amount of oxygen radicals existing near the center portion of the substrate 1 to be reduced, by which the deposition of protection film deposited on the side wall of the gate electrode 7 is reduced.

On the other hand, the CD shift at the circumference portion can be increased by increasing the amount of oxygen contained in the second processing gas 36-2 supplied through the circumference-side gas supply port 34-2 (for example to 7 sccm), so that the amount of oxygen radicals existing near the outer circumference portion of the substrate 1 is increased, by which the deposition of protection film deposited on the side wall of the gate electrode 7 is increased and thus the CD shift at the outer circumference portion is increased.

Furthermore, it is assumed that when 100 sccm of hydrogen bromide, 100 sccm of chlorine and 5 sccm of oxygen are supplied as the first processing gas 36-1, and 5 sccm of oxygen is supplied as the second processing gas 36-2, the CD shift at the center and at the outer circumference of the substrate 1 are 2 nm and 5 nm, respectively. In this case, by either increasing the CD shift at the center portion or decreasing the CD shift at the outer circumference portion, the in-plane CD shift distribution of the substrate 1 can be made more uniform.

The CD shift at the center portion can be increased by reducing the amount of chlorine contained in the first processing gas 36-1 supplied through the center-side gas supply port 34-1 (for example to 90 sccm), which causes the amount of chlorine radicals existing near the center portion of the substrate 1 to reduce, by which the isotropic etching performed to the side wall of the gate electrode 7 is weakened and the CD shift at the center portion of the substrate is increased. Moreover, the CD shift at the center portion can also be increased by increasing the amount of oxygen contained in the first processing gas 36-1 supplied through the center-side gas supply port 34-1 (for example to 7 sccm), which causes the amount of oxygen radicals existing near the center portion of the substrate 1 to be increased, by which the deposition of protection film deposited on the side wall of the gate electrode 7 is increased.

On the other hand, the CD shift at the circumference portion can be decreased by reducing the amount of oxygen contained in the second processing gas 36-2 supplied through the circumference-side gas supply port 34-2 (for example to 3 sccm), which causes the amount of oxygen radicals existing near the outer circumference portion of the substrate 1 to reduce, by which the deposition of protection film deposited on the side wall of the gate electrode 7 is reduced and the CD shift at the outer circumference portion is thus decreased.

As described, the in-plane distribution of CD shift of the substrate 1 can be controlled by respectively supplying a first processing gas 36-1 and a second processing gas 36-2 having different compositions through the center-side gas supply port 34-1 disposed at a position opposing to the substrate 1 and the circumference-side gas supply port 34-2 formed on the upper corner portion of the processing chamber 26, and as a result, the in-plane uniformity thereof can be improved. Furthermore, by supplying only non-corrosive processing gas (which in the example of embodiment 3 is oxygen) through the second gas supply pipe 30-2, it becomes possible to prevent corrosion of the gas supply groove 74 and the circumference-side gas supply port 34-2, and prevent deterioration of the production yield of the semiconductor device.

According to embodiment 3, oxygen is used as the non-corrosive processing gas to be supplied to the second gas supply pipe 30-2, but the gas is not restricted thereto, and for example, fluorocarbon-based processing gas containing carbon, such as carbon tetrafluoride, can be used. For example, an undissociated carbon tetrafluoride is extremely stable, and will not cause corrosion of metallic components and the like. On the other hand, it will be dissociated in plasma 38, generating fluorine (F) radicals having corrosiveness to metal, but it will not be dissociated around the gas supply groove 74 and the circumference gas supply port 34-2 since there is no plasma 38 generated in that area, so as a result, it will not have corrosiveness to metal. Thus, when using fluorocarbon-based processing gas containing carbon, such as the carbon tetrafluoride, carbon-based reaction products having strong deposition property are generated as mentioned earlier which become depositing components, depositing on the side wall of the gate electrode 7. As a result, the deposition acts as a protection film for the side wall of the gate electrode 7, increasing the CD shift of the gate etching process.

Hereafter, the actual processing method is described, taking the gate etching process as an example. It is now assumed that when a mixed gas containing 100 sccm of hydrogen bromide, 100 sccm of chlorine and 5 sccm of oxygen is used as the first processing gas 36-1, and 50 sccm of carbon tetrafluoride is used as the second processing gas 36-2, the CD shift at the center and at the outer circumference of the substrate 1 are 5 nm and 2 nm, respectively. In this case, by either decreasing the CD shift at the center portion or increasing the CD shift at the outer circumference portion, the in-plane CD shift distribution of the substrate 1 can be made more uniform.

The CD shift at the center portion can be decreased by increasing the amount of chlorine contained in the first processing gas 36-1 supplied through the center-side gas supply port 34-1 (for example to 110 sccm), which causes the amount of chlorine radicals existing near the center portion of the substrate 1 to increase, by which the isotropic etching performed to the side wall of the gate electrode 7 is enhanced and the CD shift at the center portion of the substrate is decreased. In addition, the CD shift at the center portion can also be decreased by reducing the amount of oxygen contained in the first processing gas 36-1 supplied through the center-side gas supply port 34-1 (for example to 3 sccm), which causes the amount of oxygen radicals existing near the center portion of the substrate 1 to be reduced, by which the deposition of protection film deposited on the side wall of the gate electrode 7 is reduced.

On the other hand, the CD shift at the circumference portion can be increased by increasing the amount of carbon tetrafluoride contained in the second processing gas 36-2 supplied through the circumference-side gas supply port 34-2 (for example to 60 sccm), so that the amount of depositing carbon-based reaction products existing near the outer circumference portion of the substrate 1 is increased, by which the deposition of protection film deposited on the side wall of the gate electrode 7 is increased and thus the CD shift at the outer circumference portion is increased.

Furthermore, it is assumed that when 100 sccm of hydrogen bromide, 100 sccm of chlorine and 5 sccm of oxygen are supplied as the first processing gas 36-1, and 50 sccm of carbon tetrafluoride is supplied as the second processing gas 36-2, the CD shift at the center and at the outer circumference of the substrate 1 are 2 nm and 5 nm, respectively. In this case, by either increasing the CD shift at the center portion or decreasing the CD shift at the outer circumference portion, the in-plane CD shift distribution of the substrate 1 can be made more uniform.

The CD shift at the center portion can be increased by reducing the amount of chlorine contained in the first processing gas 36-1 supplied through the center-side gas supply port 34-1 (for example to 90 sccm), which causes the amount of chlorine radicals existing near the center portion of the substrate 1 to reduce, by which the isotropic etching performed to the side wall of the gate electrode 7 is weakened and the CD shift at the center portion of the substrate is increased. Moreover, the CD shift at the center portion can also be increased by increasing the amount of oxygen contained in the first processing gas 36-1 supplied through the center-side gas supply port 34-1 (for example to 7 sccm), which causes the amount of oxygen radicals existing near the center portion of the substrate 1 to be increased, by which the deposition of protection film deposited on the side wall of the gate electrode 7 is increased.

On the other hand, the CD shift at the circumference portion can be decreased by reducing the amount of carbon tetrafluoride contained in the second processing gas 36-2 supplied through the circumference-side gas supply port 34-2 (for example to 40 sccm), which causes the amount of depositing carbon-based reaction products to be reduced, by which the deposition of protection film deposited on the side wall of the gate electrode 7 is reduced and the CD shift at the outer circumference portion can thus be decreased.

According to embodiments 1 through 3 of the present invention, processing gases 36 are supplied through the center-side gas supply port 34-1 and the circumference-side gas supply port 34-2 during the etching process. The purpose of such arrangement is to control the CD shift distribution of the substrate 1, as mentioned earlier, but it also has an effect to prevent generation of particles. For example, if the processing gas is not supplied from either the center-side gas supply port 34-1 or the circumference-side gas supply port 34-2 (for example, if not supplied from the circumference-side gas supply port 34-2), the reaction products generated during the etching process are transferred upstream than the outer-side gas supply port 34-2 due to diffusion, causing deposits to adhere on the surface of the earth ring 132 facing the ring 136 or the surface of the ring 136 facing the earth ring 132, and become the possible cause of adhesion of particles on the surface of the substrate 1. This diffusion of reaction products toward the upstream side can be prevented by supplying gas also from the circumference-side gas supply port 34-2, by which the adhesion of particles on the substrate can be prevented.

Therefore, during the etching process, it is preferable that the processing gases are supplied from both gas supply ports. If it is possible to achieve a uniform CD shift distribution of substrate 1 without supplying processing gas from one of the gas supply ports (such as the circumference-side gas supply port 34-2), then by supplying a small amount of processing gas (such as argon or other rare gases) having little influence on the CD shift from the other gas supply port (which in this example is the circumference-side gas supply port 34-2), it becomes possible to maintain a uniform CD shift distribution of the substrate 1 while preventing adhesion of particles on the surface of the substrate 1.

What is claimed is:

1. A plasma etching apparatus comprising:
a substantially cylindrical processing chamber for performing a plasma process to a substrate;
a substrate stage for supporting the substrate;
at least two gas feed sources for feeding processing gas to the processing chamber;
a first gas supply port for supplying the processing gas into the processing chamber;
a second gas supply port for supplying the processing gas into the processing chamber disposed separately from the first gas supply port;
a vacuum pump for reducing the pressure within the processing chamber; and
an electromagnetic wave feeding means for feeding electromagnetic waves to the processing chamber;
wherein the first gas supply port is disposed at a position opposing to the substrate and the second gas supply port is disposed so as to form uniform openings along a circumferential direction on either an upper corner portion of the processing chamber or a side wall of the processing chamber, by which, an axisymmetric processing gas flow is created in the processing chamber.

2. The plasma etching apparatus according to claim 1, wherein the second gas supply port is disposed on the upper corner portion of the processing chamber and at an intermediate height between the first gas supply port and the substrate.

3. The plasma etching apparatus according to claim 1, wherein the second gas supply port is disposed on the side wall of the processing chamber and at an intermediate height between the first gas supply port and the substrate.

4. The plasma etching apparatus according to claim 1, wherein the second gas supply port is composed of a gas supply groove for guiding the processing gas to the whole circumference of the processing chamber in the circumferential direction, a plurality of holes connected to the gas supply groove, and openings uniform in the circumferential direction and connected to the plurality of holes, which are formed within the side wall of the substantially cylindrical processing chamber.

5. The plasma etching apparatus according to claim 1, wherein the second gas supply port is composed of a gas supply groove for guiding the processing gas to the whole circumference of the processing chamber in the circumferential direction, a plurality of holes connected to the gas supply groove, and openings uniform in the circumferential direction and connected to the plurality of holes, which are formed within the side wall of the substantially cylindrical processing chamber; and
a conductance of the circumferential flow of the gas supply groove is made greater than a conductance of the flow of the plurality of holes.

6. The plasma etching apparatus according to claim 1, wherein the second gas supply port is composed of a gas supply groove for guiding the processing gas to the whole circumference of the processing chamber in the circumferential direction, a plurality of holes connected to the gas supply groove, and openings uniform in the circumferential direction and connected to the plurality of holes, which are formed within the side wall of the substantially cylindrical processing chamber;
a conductance of the circumferential flow of the gas supply groove is made greater than a conductance of the flow of the plurality of holes; and
a gap uniform in the circumferential direction is formed between the plurality of holes and the circumferentially uniform openings by which a conductance of the flow within the gap is made greater than the conductance of the flow of the plurality of holes.

7. The plasma etching apparatus according to claim 1, wherein a round antenna or waveguide is disposed on the upper portion of the processing chamber, and the center axis of the round antenna or waveguide is disposed to correspond to the center axis of a ring-shaped magnetic field forming coil and the center axis of the wall of the substantially cylindrical processing chamber.

8. The plasma etching apparatus according to claim 1, further comprising a control unit for supplying processing gas through both the first gas supply port and the second gas supply port.

9. The plasma etching apparatus according to claim 1, wherein a control unit supplies gases through the first gas supply port and the second gas supply port, independently controlling the respective compositions or the flow rates or both the compositions and the flow rates of the gases.

10. The plasma etching apparatus according to claim 1, further comprising a control unit for supplying a non-corrosive gas through the second gas supply port.

11. A plasma etching method using a plasma etching apparatus comprising:
a substantially cylindrical processing chamber for performing a plasma process to a substrate;
a substrate stage for supporting the substrate;
at least two gas feed sources for feeding processing gas to the processing chamber;
a first gas supply port for supplying the processing gas into the processing chamber;
a second gas supply port for supplying the processing gas into the processing chamber disposed separately from the first gas supply port;
a vacuum pump for reducing the pressure within the processing chamber; and
an electromagnetic wave feeding means for feeding electromagnetic waves to the processing chamber;
the method comprising supplying gas through a first gas supply port disposed at a position opposing to the substrate and supplying gas through a second gas supply port disposed so as to form uniform openings along a circumferential direction on either an upper corner portion of the processing chamber or a side wall of the processing chamber, so as to create an axisymmetric processing gas flow in the processing chamber.

12. The plasma etching method according to claim 11, wherein the processing gas is supplied through both the first gas supply port and the second gas supply port.

13. The plasma etching method according to claim 11, further comprising supplying the gases through the first gas supply port and the second gas supply port while independently controlling the respective compositions or the flow rates or both the compositions and the flow rates of the gases.

14. The plasma etching method according to claim 11, further comprising supplying a non-corrosive gas through the second gas supply port.
